(19) United States
(12) Patent Application Publication
(10) Pub. No.: US 2011/0140269 A1
(43) Pub. Date: Jun. 16, 2011

(54) Semiconductor device and method for manufacturing the same

(75) Inventor: Fumihiro Bekku, Kanagawa (JP)

(73) Assignee: Renesas Electronics Corporation, Kawasaki-shi, Kanagawa (JP)

(21) Appl. No.: 12/926,558

(22) Filed: Nov. 24, 2010

(30) Foreign Application Priority Data
Dec. 15, 2009 (JP) 2009-284100

(51) Int. Cl. H01L 23/48; H01L 21/60

(52) U.S. Cl. 257/737; 438/121; 257/E23.021; 257/E21.506

(57) ABSTRACT

A semiconductor device includes an electrode pad and a protective insulating film having an opening to expose the electrode pad. The semiconductor device further includes a bump (resin core bump) that includes a bump core (resin core) formed on the protective insulating film and a conductive layer formed on the bump core. The semiconductor device further includes an interconnect that connects the conductive layer and the electrode pad. The bump core is in the form of a laminate of plural resin layers (for example, first and second resin layers) that have different elastic modulus.

This application is based on Japanese patent application No. 2009-284100, the content of which is incorporated hereinto by reference.

### BACKGROUND

1. Technical Field

The present invention relates to a semiconductor device and a method for manufacturing the same.

2. Related Art

As for a bump of a semiconductor device, Japanese Laid-open patent publication NO. 02-272737 discloses a resin core bump including a bump core made of a resin and a conductive film applied onto the surface of the bump core to exhibit excellent elasticity.

Meanwhile, Japanese Laid-open patent publication NO. 2003-037135 discloses a technology of forming a bump by providing a conductor pattern on the surface of an insulating substrate, providing a conductive protrusion (bump core) on the conductor pattern, and forming a conductor interconnect on the conductive protrusion through selective etching.

According to the technology that is disclosed in Japanese Laid-open patent publication No. 2003-037135, the conductive protrusion is formed of metal conductors (first protrusion member and second protrusion member) of two layers having different hardness, using a plating method.

The resin core bump can be stably connected to an external electrode of amounting substrate using elasticity of the bump core thereof. Accordingly, an elastic characteristic of a resin for the bump core is very important to obtain a good connectivity between the resin core bump and the external electrode.

### SUMMARY

The present inventor has recognized as follows. According to the technology that is disclosed in Japanese Laid-open patent publication NO. 02-272737, since the bump core (resin core) is formed of a resin of a single layer, the elastic characteristic of the resin core bump depends on the intrinsic hardness of the resin of a single layer.

The resin core and the resin core bump need to have the repulsive force with a magnitude of a certain degree. However, if the hardness of the resin core is increased as a result of emphasizing the repulsive force, deformability of the resin core and the resin core bump is impaired.

As a result, the sufficient connectivity between the bump and the external electrode is not likely to be obtained. Specifically, there is a possibility that, if inclination, warpage, unevenness, or protrusions on the surface due to impurities or the like are present on the top surface of an external electrode or a bump, the adhesion between the bump and the external electrode becomes insufficient, which may result in an insufficient connectivity between the bump and the external electrode.

According to the technology that is disclosed in Japanese Laid-open patent publication NO. 2003-037135, the bump core is made of a metal conductor. This is believed to contribute to the excellent strength of the bump core. However, since deformability of the metal is significantly lower than that of the resin, the deformation amount of the bump core that is made of the metal conductor is very small, even though the bump core has a laminate structure. For this reason, even with the configuration disclosed in Japanese Laid-open patent publication NO. 2003-037135, good adhesion and connectivity are not obtained between the bump and the external electrode sometimes.

As such, it is difficult for the bump to have both the sufficient adhesion and sufficient repulsive force to improve the connectivity between the bump and the external electrode.

In one embodiment, there is provided a semiconductor device including an electrode pad, a protective insulating film having an opening configured to expose the electrode pad, a bump including a bump core formed on the protective insulating film and a conductive layer formed on the bump core, and an interconnect that connects the conductive layer and the electrode pad. The bump core has a laminate structure of plural resin layers having different elastic modulus.

According to the present invention, the bump core of the bump has a laminate structure of plural resin layers that have the different elastic modulus. For this reason, a good adhesion between the bump and the external electrode may be obtained based on the principle of any one of the followings (1) and (2).

(1) When the resin layer having a relatively small elastic modulus (soft) is located at the uppermost layer of the laminate structure, the resin layer of the surface layer deforms to fit to the shape of the external electrode through the conductive layer. Thereby, a good adhesion between the bump and the external electrode may be obtained. For this reason, even though inclination, warpage, unevenness, or protrusions on the surface due to impurities or the like are exist on the top surface of the external electrode or the bump, a good adhesion between the bump and the external electrode may be obtained.

(2) Next, the case in which one resin layer having a relatively small elastic modulus (soft) is located at the lower layer or the intermediate layer of the laminate structure and another resin layer having a elastic modulus greater than the elastic modulus of the former resin layer is located at the uppermost layer of the laminate structure will be described. In this case, when the former resin layer deforms, the latter resin layer and the conductive layer are inclined to comply with the morphology of the external electrode. For this reason, a good adhesion between the bump and the external electrode may be obtained.

The bump core may be configured to have the sufficient repulsive force by the existence of the resin layer having a relatively large elastic modulus.

Accordingly, the bump may be configured to have the sufficient adhesion and sufficient repulsive force, and connectivity between the bump and the external electrode may be improved.

In another embodiment, there is provided an electronic apparatus including the semiconductor device and a mounting substrate having an electrode. The bump is connected to the electrode of the mounting substrate.

In still another embodiment, there is provided a method for manufacturing a semiconductor device that includes forming a protective insulating film having an opening configured to expose an electrode pad, on a substrate where the electrode pad is formed, laminating a plurality of photosensitive resin films that come to have different elastic modulus after curing on the protective insulating film, exposing, developing, and curing the plurality of photosensitive resin films to form a laminate structure of a plurality of resin layers having different elastic modulus on the protective insulating film as a bump core, and forming a conductive layer extending from an upper portion of the bump core to an upper portion of the electrode pad.

According to the present invention, the bump of the semiconductor device can be configured to have the sufficient adhesion and sufficient repulsive force, and connectivity between the bump and the external electrode may be improved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view illustrating a semiconductor device according to an embodiment;

FIG. 2 is a cross-sectional view illustrating the semiconductor device according to the embodiment;

FIGS. 3A to 3E are cross-sectional views illustrating a process sequence of a method for manufacturing a semiconductor device according to the embodiment;

FIG. 4 is a cross-sectional view illustrating an electronic apparatus according to the embodiment;

FIGS. 5A to 5C are cross-sectional views illustrating the behavior of a resin core bump at the time of mounting;

FIGS. 6A and 6B are cross-sectional views illustrating the behavior of the resin core bump at the time of mounting in the case in which warpage is generated in an electrode of a mounting substrate;

FIGS. 7A and 7B are cross-sectional views illustrating the behavior of the resin core bump at the time of mounting in the case in which the electrode of the mounting substrate is inclined;

FIG. 8 is a diagram illustrating an example of deformation characteristics of plural resin layers and a resin core;

FIG. 9 is a diagram illustrating another example of the deformation characteristics of the plural resin layers and the resin core;

FIGS. 10A and 10B are cross-sectional views illustrating the behavior of a resin core bump of a semiconductor device according to a first modification;

FIG. 11 is a plan view of a semiconductor device according to a second modification;

FIG. 12 is a cross-sectional view of the semiconductor device according to the second modification;

FIG. 13 is a plan view of a semiconductor device according to a third modification; and

FIG. 14 is a cross-sectional view of the semiconductor device according to the third modification.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hatching is attached in the plan views in order to facilitate the understanding of the embodiments of the present invention. Embodiments of the present invention will be explained below, referring to the attached drawings. Note that any similar constituents will be given the same reference numerals or symbols in all drawings, and explanations therefore will not be repeated.

First, a semiconductor device 100 according to this embodiment will be described.

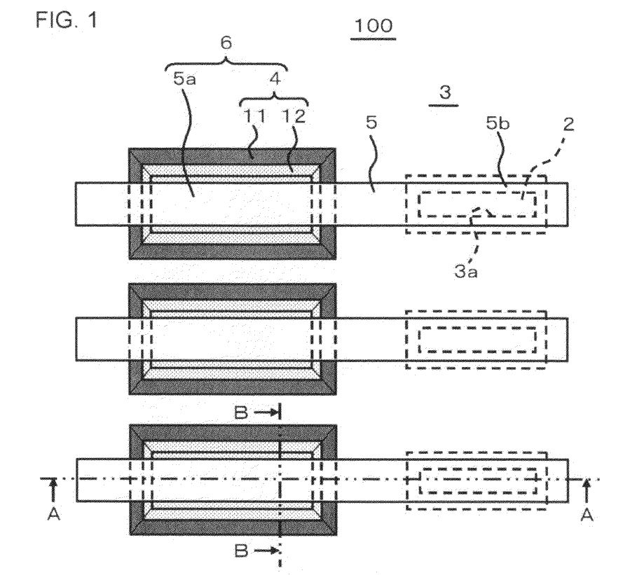

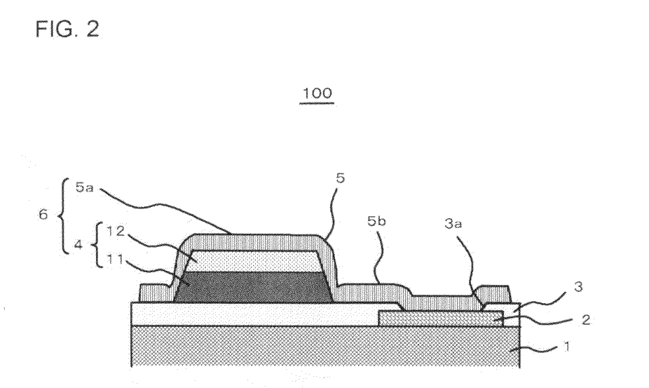

FIG. 1 is a plan view of the semiconductor device 100 according to the embodiment and FIG. 2 is a cross-sectional view taken along the line A-A of FIG. 1.

The semiconductor device 100 according to this embodiment includes an electrode pad 2 and a protective insulating film 3 in which an opening 3a to expose the electrode pad 2 is formed. The semiconductor device 100 further includes a bump (resin core bump 6) including a bump core (resin core 4) formed on the protective insulating film 3 and a conductive layer 5a formed on the bump core. The semiconductor device 100 further includes an interconnect 5b that connects the conductive layer 5a and the electrode pad 2. The bump core has a laminate structure of plural resin layers (for example, first and second resin layers 11 and 12) that have different elastic modulus.

Hereinafter, the configuration will be described in detail.

The semiconductor device 100 includes a semiconductor substrate 1. In the semiconductor substrate 1, elements (not shown in the drawings), such as transistors forming a circuit, are formed along with the electrode pad 2.

The protective insulating film 3 is formed on the semiconductor substrate 1 and the resin core 4 of the resin core bump 6 is formed on the protective insulating film 3.

The semiconductor device 100 includes an interconnect 5 that extends from the upper portion of the resin core 4 to the upper portion of the electrode pad 2. A portion of the interconnect 5 provided on the resin core 4 forms a conductive layer 5a. The conductive layer 5a and the resin core 4 form the resin core bump 6. Meanwhile, a portion of the interconnect 5 other than the conductive layer 5a forms an interconnect 5b.

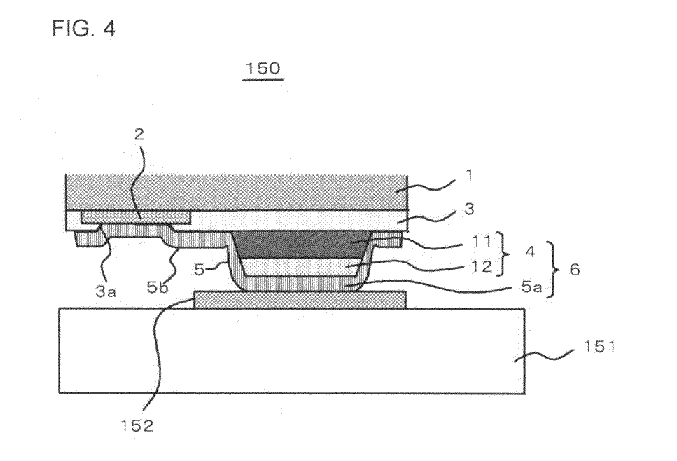

The resin core bump 6 is connected to an electrode 152 (FIG. 4) of amounting substrate 151 to be described below. At the time of connection, since the resin core bump 6 and the electrode 152 are pressed against each other, the resin core 4 of the resin core bump 6 is compressed and deformed.

The resin core 4 of the resin core bump 6 has a laminate structure of the plural resin layers 11 and 12 that have different elastic modulus.

The number of resin layers 11 and 12 that constitute the resin core 4 is an arbitrary number that is equal to or more than 2. However, in this embodiment, the resin core 4 is configured using two layers of the resin layers 11 and 12.

Either the elastic modulus of the first resin layer 11 that is located at a lower layer or the elastic modulus of the second resin layer 12 that are located at an upper layer may be smaller (softer) than the other. However, in this embodiment, the elastic modulus of the second resin layer 12 of the upper layer is relatively small (soft) and the elastic modulus of the resin layer 11 of the lower layer is relatively large (hard).

The first and second resin layers 11 and 12 can be configured using a thermosetting resin, such as a phenol resin, an epoxy resin, a polyimide resin, an amino resin, an unsaturated polyester resin, a silicon resin or an allyl resin. Each of the first and second resin layers 11 and 12 may have an insulating property.

The magnitude of the elastic modulus of each of the resin layers 11 and 12 in the resin core 4 is mainly determined by a material, and the elastic modulus of each of the resin layers 11 and 12 can be adjusted by appropriately selecting the material of each of the resin layers 11 and 12.

The elastic modulus of the resin layers 11 and 12 can be adjusted by selecting the kind and the amount of an additive or a solvent in addition to selection of a base material such as polyimide and epoxy. Also, the elastic modulus of the resin layers 11 and 12 can be adjusted by mixing the base material with an inorganic powder.

Also, the elastic modulus of the resin layers 11 and 12 can be adjusted by adjusting a temperature profile at the time of curing, when the resin layers 11 and 12 are made of thermosetting materials.

The deformation amount of each of the resin layers 11 and 12 in the resin core 4 is mainly determined by the elastic modulus and the shape of each of the resin layers 11 and 12. The amount of deformation attributable to the shape depends on a ratio of an area pressed at the time of mounting, that is, an area of a top portion of each of the resin layers 11 and 12, to an area of a region where the resin is deformed by pressing, that is, an area defined by the side of each of the resin layers 11 and 12. In other words, the deformation amount of each of the resin layers 11 and 12 increases as the area of the top portion thereof decreases. The deformation amount of each of the resin layers 11 and 12 generally increases as an inclination angle of the side thereof increases. The deformation amount of each of the resin layers 11 and 12 increases as the thickness thereof increases. For this reason, the deformation amount of the resin core 4 can be adjusted by adjusting a thickness ratio of the resin layers 11 and 12.

For example, the resin core 4 is shaped to be spread toward the bottom. That is, the sectional area of the resin core 4 gradually increases from a top portion to a bottom portion of the resin core 4.

For example, an area of the bottom portion of the second resin layer 12 of the upper side is approximately equal to an area of the top portion of the first resin layer 11 of the lower side.

For example, the resin core bumps 6 are linearly arranged.

The respective resin core bumps 6 are disposed apart from each other.

Next, a method for manufacturing a semiconductor device according to the embodiment will be described.

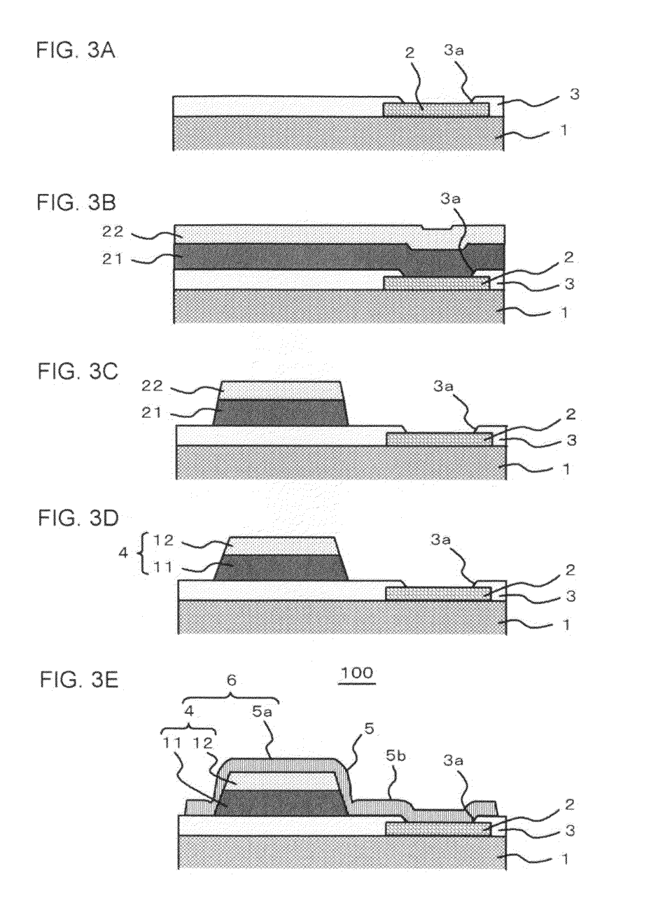

FIGS. 3A to 3E are cross-sectional views illustrating a process sequence of a method for manufacturing a semiconductor device according to the embodiment.

The method for manufacturing a semiconductor device according to this embodiment includes first to fourth processes. In the first process, a protective insulating film 3 having an opening 3a to expose an electrode pad 2 is formed on a substrate (semiconductor substrate 1) where the electrode pad 2 is formed. In the second process, plural photosensitive resin films (for example, first and second photosensitive resin films 21 and 22) which become to have different elastic modulus after curing are laminated on the protective insulating film 3. In the third process, the plural photosensitive resin films are exposed, developed, and cured to form a laminate structure of the plural resin layers (for example, the first and second resin layers 11 and 12) having different elastic modulus as the bump core (resin core 4) on the protective insulating film 3. In the fourth process, a conductive layer (interconnect 5) is formed to extend from an upper portion of the bump core to an upper portion of the electrode pad 2.

Hereinafter, the process will be described in greater detail.

First, elements (not shown in the drawings), such as transistors which form a circuit are formed on the semiconductor substrate 1, and a multi-layered interconnect layer (not shown in the drawings) is formed on the semiconductor substrate 1. The multi-layered interconnect layer has the electrode pad 2 on the uppermost layer thereof.

Next, the protective insulating film 3 is formed on the multi-layered interconnect layer. The protective insulating film 3 can be configured by a silicon oxide film, a film laminate of a silicon oxide film and a silicon nitride film, or a silicon nitride film.

Next, the opening 3a is formed by selectively removing the protective insulating film 3. The opening 3a is provided on the electrode pad 2 and the electrode pad 2 is exposed through the protective insulating film 3 (refer to FIG. 3A) at the opening 3a.

Next, as shown in FIG. 3B, the first photosensitive resin film 21 is formed on the protective insulating film 3 and the electrode pad 2 through a spin coating method. Next, the second photosensitive resin film 22 that has different elastic modulus after curing from that of the first photosensitive resin film 21 (that has the elastic modulus smaller than that of the first photosensitive resin film 21 in the case of this embodiment) is formed on the first photosensitive resin film 21 through a spin coating method.

Next, as shown in FIG. 3C, the first and second photosensitive resin films 21 and 22 selectively remain on the protective insulating film 3 by developing the first and second photosensitive resin films 21 and 22 after partially exposing the first and second photosensitive resin films 21 and 22 through a photomask (not shown in the drawings).

Next, as shown in FIG. 3D, the first and second photosensitive resin films 21 and 22 are cured by a heat treatment.

In this way, the resin core 4 that has a laminate structure of the first resin layer 11 composed of the first photosensitive resin film 21 and the second resin layer 12 composed of the second photosensitive resin film 22 can be formed on the protective insulating film 3.

Next, as shown in FIG. 3E, the interconnect 5 is formed to extend from an upper portion of the resin core 4 to an upper portion of the electrode pad 2.

That is, after forming the conductive film (for example,* Au film (not shown in the drawings)) on the resin core 4, the protective insulating film 3, and the electrode pad 2 using a sputtering method, a resist pattern (not shown in the drawings) is formed on the conductive film. Next, the conductive film is selectively removed by etching the conductive film using the resist pattern as a mask, and the conductive film is processed in the shape of the interconnect 5. Then, the resist pattern is removed.

The portion of the interconnect 5 provided on the resin core 4 is the conductive layer 5a that constitutes the resin core bump 6 together with the resin core 4. The portion of the interconnect 5 other than the conductive layer 5a constitutes the interconnect 5b that connects the conductive layer 5a and the electrode pad 2.

In this way, the semiconductor device 100 can be manufactured.

Next, an electronic apparatus 150 according to an embodiment will be described.

FIG. 4 is a cross-sectional view of the electronic apparatus 150 according to the embodiment.

The electronic apparatus 150 according to this embodiment includes the semiconductor device 100 according to this embodiment and the mounting substrate 151 having the electrode 152. The bump core is connected to the electrode 152 of the mounting substrate 151.

By mounting the semiconductor device 100 on the mounting substrate 151 as shown in FIG. 4, the electronic apparatus 150 can be manufactured.

That is, the semiconductor device 100 and the mounting substrate 151 can be electrically connected by connecting the resin core bump 6 of the semiconductor device 100 to the electrode 152 of the mounting substrate 151 and mounting the semiconductor device 100 on the mounting substrate 151. The electrode 152 is, for example, a land. However, the electrode 152 is not limited to the land.

After mounting the semiconductor device 100 on the mounting substrate 151, amounting sealing resin (not shown in the drawings) can be filled into a gap between the mounting substrate 151 and the semiconductor device 100, and then can be cured.

In this case, when the semiconductor device 100 is a driver for a liquid crystal display device, the semiconductor device 100 is mounted on the mounting substrate 151 corresponding to a glass substrate in the form of chip-on-glass (COG).

Alternatively, the semiconductor device 100 may be mounted on a wiring board functioning as the mounting substrate 151 or mounted on a film substrate in the form of chip-on-film (COF).

The resin core bump 6 is pressed against the electrode 152 functioning as the external electrode by mounting, so that the resin core bump 6 is compressed and deformed.

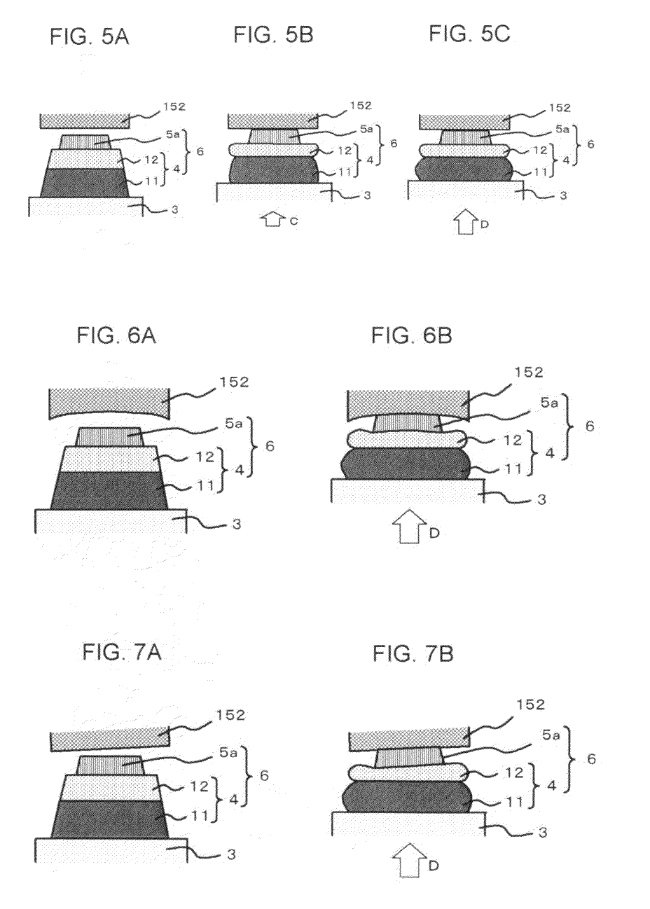

Next, the behavior of the resin core bump 6 at the time of mounting will be described with reference to FIGS. 5A to 7B.

FIGS. 5A to 7B show the behavior of the resin core bump 6 at the time of mounting and are cross-sectional views taken along the line B-B of FIG. 1. Among FIGS. 5A to 7B, FIGS. 5A to 5C show the behavior in the case in which the electrode 152 of the mounting substrate 151 and the resin core bump 6 are parallel to each other, FIGS. 6A and 6B show the behavior in the case in which the electrode 152 of the mounting substrate 151 is warped, and FIGS. 7A and 7B show the behavior in the case in which the electrode 152 of the mounting substrate 151 is inclined.

First, as shown in FIG. 5A, the case in which the electrode 152 is parallel to the top surface of the resin core bump 6 will be described. In this case, as shown in FIGS. 5B and 5C, the top surface of the electrode 152 and the top surface of the resin core bump 6 are brought into contact in parallel to each other and are mutually pressed against each other. Arrows C and D in FIGS. 5B and 5C show a pressing direction of the resin core bump 6 against the electrode 152 of the mounting substrate 151. The length of the arrows C and D indicates the magnitude of the pressing force (the longer arrow represents a larger magnitude of the pressing force).

In this embodiment, the second resin layer 12 that has a relatively small elastic modulus (soft) is positioned at the uppermost layer of the resin core 4. For this reason, the second resin layer 12 deforms to fit to a shape of the electrode 152 through the conductive layer 5a. Thereby, a good adhesion between the resin core bump 6 and the electrode 152 can be obtained.

For this reason, even though the warpage, the unevenness, or the protrusions on the surface due to impurities or the like are exist on the top surface of the electrode 152 or the resin core bump 6, a good adhesion between the resin core bump 6 and the electrode 152 can be obtained. For example, as shown in FIG. 6A, when the electrode 152 is warped in a concave shape, as shown in FIG. 6B, the conductive layer 5a comes to have a warpage to reflect the warpage of the electrode 152, and the second resin layer 12 deforms to comply with the morphology of the electrode 152 through the conductive layer 5a. Thereby, a good adhesion between the resin core bump 6 and the electrode 152 can be obtained.

Next, as shown in FIG. 7A, the case in which the electrode 152 is inclined relative to the top surface of the resin core bump 6 will be described. In this case, as shown in FIG. 7B, since the resin core bump 6 is pressed against the inclined electrode 152, the conductive layer 5a is inclined to comply with the morphology of the electrode 152 and the second resin layer 12 is deformed to absorb the inclination of the conductive layer 5a. Thereby, a good adhesion between the resin core bump 6 and the electrode 152 can be obtained.

Even in this case, even though the warpage, the unevenness, or the protrusions on the surface due to impurities or the like are exist on the top surface of the electrode 152 or the resin core bump 6, a good adhesion between the resin core bump 6 and the electrode 152 can be obtained, similar to the case of FIGS. 6A and 6B.

As such, even in any case of FIGS. 5A to 7B, since a good adhesion between the resin core bump 6 and the electrode 152 can be obtained, a contact area of the resin core bump 6 and the electrode 152 can be sufficiently secured so that a good connectivity can be obtained.

Even in any case of FIGS. 5A to 7B, the resin core 4 does not uniformly swell in the side of all directions. For this reason, even though the resin core 4 is not configured to have a small size as compared with the case in which the resin core 4 is made of a resin of one layer, a flow passage of a mounting sealing resin (non-conductive film (NCF) or non-conductive paste (NCP)) can be sufficiently secured. Accordingly, since fluidity at the time of filling the mounting sealing resin becomes superior, generation of voids in the mounting sealing resin can be suppressed. Thereby, adhesion between the semiconductor device 100 and the mounting substrate 151 can be improved. Since the resin core 4 and the resin core bump 6 can be formed to have a large size as much as possible, an electric connection area between the resin core bump 6 and the electrode 152 can be increased.

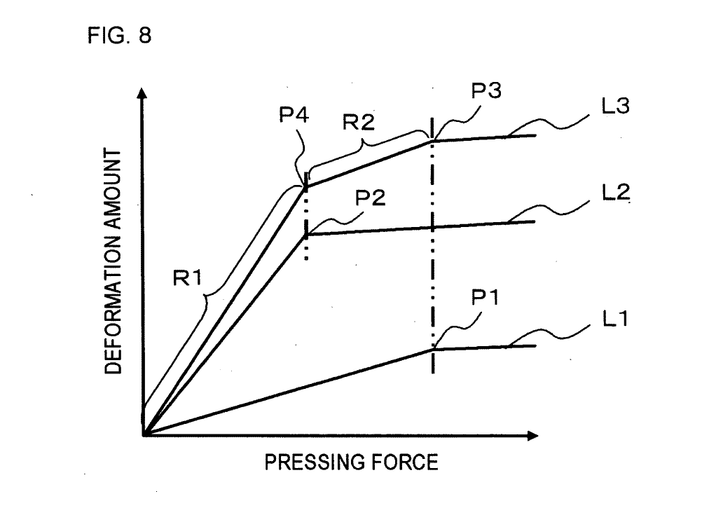

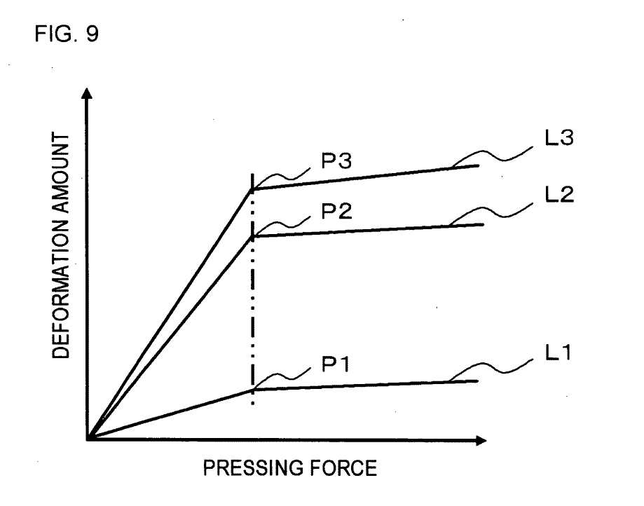

Next, an example of deformation characteristics of the plural resin layers 11 and 12 and the resin core 4 will be described with reference to FIGS. 8 and 9.

In FIGS. 8 and 9, a horizontal axis indicates the pressing force (direction is a height direction of the resin core bump 6) of the resin core bump 6 with respect to the electrode 152 of the mounting substrate 151 and a vertical axis indicates the deformation amount.

In FIGS. 8 and 9, a curved line L1 indicates a deformation characteristic of the first resin layer 11, a curved line L2 indicates a deformation characteristic of the second resin layer 12, and a curved line L3 indicates a deformation characteristic of the resin core 4.

As shown in FIGS. 8 and 9, in the first and second resin layers 11 and 12, the deformation amount linearly increases until the constant pressing force is applied (until the deformation amount reaches saturation points P1 and P2 of the deformation amount). However, in a range where the pressing force equal to or more than the constant pressing force is applied, the deformation amount is saturated so that the deformation amount rarely changes even though the pressing force increases.

In this case, as shown in FIG. 8, the first resin layer 11 preferably reaches the saturation point P1 of the deformation amount after the second resin layer 12 reaches the saturation point P2 of the deformation amount. The saturation points P1 and P2 of the deformation amount can be shifted each other by appropriately setting the thickness of the first and second resin layers 11 and 12.

As such, if the pressing force where the deformation amount reaches the saturation point P1 is set to be stronger than the pressing force where the deformation amount reaches the saturation point P2, as shown in FIG. 8, the resin core 4 has a deformation characteristic of having an inflection point P4 before the deformation amount reaches a saturation point P3.

Thereby, the second resin layer 12 can be deformed such that the resin core bump 6 and the electrode 152 sufficiently adhere closely to each other, during a period until the resin core 4 reaches the inflection point P4 (region R1 in the curved line L3). If the resin core bump 6 and the electrode 152 are connected by the pressing force during a period until the resin core 4 reaches the saturation point P3 after reaching the inflection point P4 (region R2 in the curved line L3), the deformation amount of the resin core 4 with respect to the pressing force can be restricted in a range narrower than that of the case in which the resin layer is one layer. Therefore, the resin core bump 6 can be connected to the electrode 152 by the sufficient and appropriate repulsive force.

That is, in the case of the deformation characteristic shown in FIG. 8, the repulsive force of the resin core bump 6 at the time of being pressed against the electrode 152 is mainly determined by an elastic characteristic of the second resin layer 12 and the amount of the resin spreading to the side in an initial step of mounting (refer to FIG. 5B). If the resin core bump 6 is strongly pressurized, the repulsive force of the resin core bump 6 at the time of being pressed to the electrode 152 is mainly determined by an elastic characteristic of the first resin layer 11 and the amount of the resin spreading to the side (refer to FIGS. 5C, 6B, and 7B). For this reason, in the initial step, the resin core bump 6 softly adheres closely to the electrode 152. Then, in a pressurizing step, the resin core bump 6 becomes a tough bump. Therefore, the deformation amount of the bump in the elements is made to be uniform and the height variation of the bump is absorbed. As a result, electric connection can be stably performed while the stress applied to the conductive layer 5a is reduced.

As shown in FIG. 9, the pressing forces where the deformation amount reaches the saturation points P1 and P2 may be equal to each other in the first resin layer 11 and the second resin layer 12. However, in this case, since the curved line L3 does not have the inflection point P4 (refer to FIG. 8), the deformation characteristic of the curved line L3 becomes equal to that of the case in which the resin layer is one layer. For this reason, the deformation amount of the resin core 4 with respect to the pressing force also becomes equal to that of the case in which the resin layer is one layer.

However, even in this case, similar to FIGS. 6B and 7B, the second resin layer 12 can be deformed such that the resin core bump 6 and the electrode 152 sufficiently adhere closely to each other. And, the resin core bump 6 can be connected to the electrode 152 by the sufficient and appropriate repulsive force.

In the embodiment described above, the resin core 4 of the resin core bump 6 has the laminate structure of the plural resin layers 11 and 12 that have different elastic modulus. The elastic modulus of the second resin layer 12 of the upper side is smaller than the elastic modulus of the first resin layer 11 of the lower side. For this reason, the second resin layer 12 is deformed to be fit to the shape of the electrode 152 through the conductive layer 5a. Thereby, a good adhesion between the resin core bump 6 and the electrode 152 can be obtained. For this reason, even though the warpage, the unevenness, or the protrusions on the surface due to impurities or the like are exist on the top surface of the electrode 152 or the resin core bump 6, a good adhesion between the resin core bump 6 and the electrode 152 can be obtained.

The resin core 4 can be configured to have the sufficient repulsive force by the existence of the first resin layer 11 having a relatively large elastic modulus.

Accordingly, the resin core bump 6 can be configured to have both the sufficient adhesion and repulsive force, and the connectivity between the resin core bump 6 and the electrode 152 can be improved.

If the thickness ratio and the plane dimension ratio of the plural resin layers 11 and 12 are appropriately set, the resin core bump 6 that has the different deformation amount for each product can be easily realized. Therefore, as compared with the case in which the resin layer is one layer, the resin core bump 6 having the various deformation amounts can be realized even though the kinds of resins handled in the manufacturing line are reduced.

Of the plural resin layers 11 and 12, the pressing force where the deformation amount of the second resin layer 12 having a relatively small elastic modulus reaches the saturation point P2 is set to be weaker than the pressing force where the deformation amount of the first resin layer 11 having a relatively large elastic modulus reaches the saturation point P1. In other words, the pressing force that is applied to the resin core bump 6 when the deformation amount of the second resin layer 12 having the relatively small elastic modulus is saturated is weaker than the pressing force that is applied to the resin core bump 6 when the deformation amount of the first resin layer 11 having the relatively large elastic modulus is saturated. Thereby, the resin core 4 that has the inflection point P4 (refer to FIG. 8) as a response for the external pressure can be realized. The resin core 4 that has the deformation characteristic with respect to the pressing force needed at the time of mounting can be easily realized.

Therefore, the resin core bump 6 that has a good connectivity can be realized and the resin core bump 6 that has an elastic characteristic suitable for a press-contact condition needed at the time of mounting can be easily realized.

Since the resin core 4 can be formed by only configuring the plural resin layers 11 and 12 having the different elastic modulus to have the laminate structure, the resin core 4 can be easily formed by a general photolithographic technology. For example, since the resin core 4 can be formed by one-time photolithographic processing, the processing number can be reduced.

As in this embodiment, if the plural resin core bumps 6 are formed apart from each other, the following effects can be obtained.

First, even in a state where the resin core bump 6 is pressed and deformed by the mounting, the flow passage of the mounting sealing resin (NCF or NCP) can be sufficiently secured. Therefore, since the fluidity at the time of filling the mounting sealing resin becomes superior, generation of voids in the mounting sealing resin can be suppressed. Thereby, adhesion between the semiconductor device 100 and the mounting substrate 151 can be improved.

Since the resin does not exist around the hem portion of the resin core bump 6, the deformation amount of when the resin core bump 6 is pressed and deformed can be sufficiently secured. Therefore, electric connection of the electrode 152 functioning as the external electrode and the resin core bump 6 can be stably performed.

<First Modification>

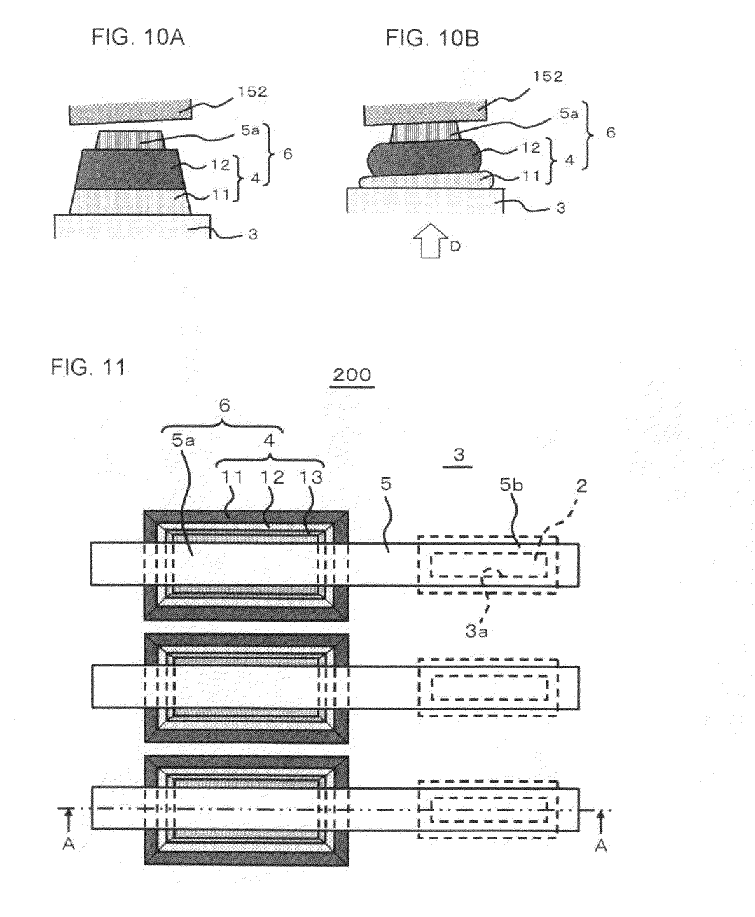

FIGS. 10A and 10B are cross-sectional views illustrating the behavior of a resin core bump 6 of a semiconductor device according to a first modification.

In the above embodiment, the case in which the elastic modulus of the resin layer of the upper side in the resin core 4 is smaller than the elastic modulus of the resin layer of the lower side is exemplified. However, in the first modification, the elastic modulus of a resin layer 11 of the lower side in a resin core 4 may be smaller than the elastic modulus of a resin layer 12 of the upper side.

In this case, as shown in FIG. 10A, the behavior in the case in which an electrode 152 is inclined relative to the top surface of the resin core bump 6 will be described.

For example, as shown in FIG. 10B, since the resin core bump 6 is pressed against the inclined electrode 152, a conductive layer 5a is inclined to comply with the morphology of the electrode 152. Since the second resin layer 12 is harder than the first resin layer 11, the second resin layer 12 is also inclined in the same way as the conductive layer 5a. The first resin layer 11 is deformed to absorb the inclination of the conductive layer 5a and the second resin layer 12. Thereby, a good adhesion between the resin core bump 6 and the electrode 152 can be obtained.

In this case, if the area of the resin layer 12 of the upper side is smaller than the area of the resin layer 11 of the lower side by some degrees, the first and second resin layers 11 and 12 may be deformed while the resin layer 12 of the upper side at the time of pressing is buried in the resin layer 11 of the lower side.

As in the first modification, when the elastic modulus of the resin layer 11 of the lower side is smaller than the elastic modulus of the resin layer 12 adjacent to the upper side of the resin layer 11, it is preferable that the area of the bottom portion of the resin layer 12 of the upper side in the resin core 4 be approximately equal to or greater than the area of the top portion of the resin layer 11 of the lower side. Thereby, the resin layer 12 of the upper side can be suppressed from being buried in the resin layer 11 of the lower side, so that an effect of reducing the height variation of the resin core bump 6 and an effect of alleviating the stress applied to the conductive layer 5a can be obtained by the same degree as the above embodiment.

<Second Modification>

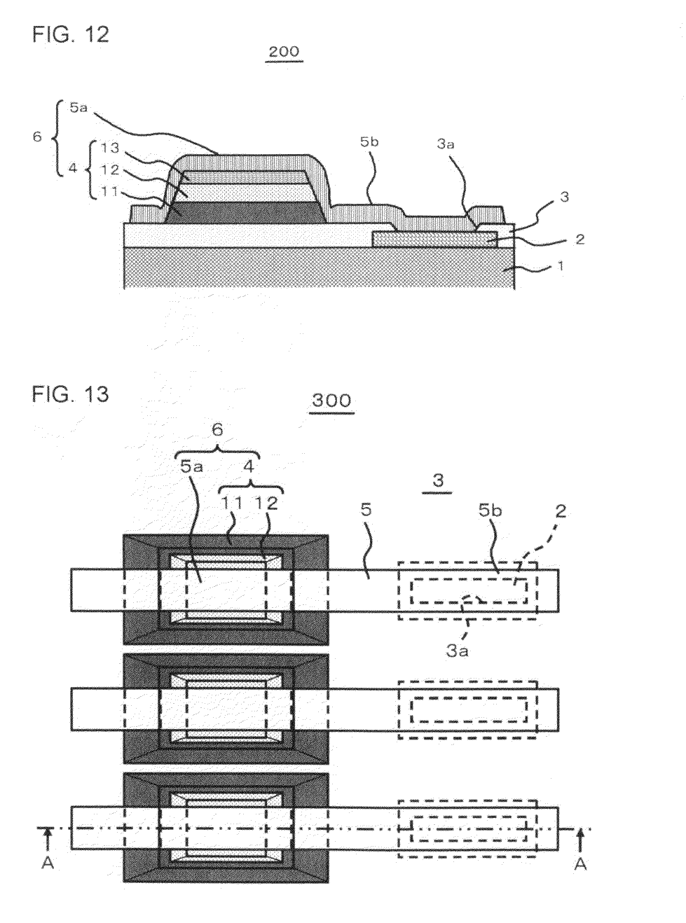

FIG. 11 is a plan view of a semiconductor device 200 according to a second modification and FIG. 12 is a cross-sectional view taken along the line A-A of FIG. 11.

In the above embodiment, the case in which the resin layers constituting the resin core 4 are two layers is exemplified. However, as shown in FIGS. 11 and 12, the resin core 4 may be configured using resin layers (for example, three layers of resin layers 11, 12, and 13) of three layers or more.

Even in this case, the elastic modulus of the resin layer of the upper side is preferably smaller than the elastic modulus of the resin layer of the lower side. That is, it is preferable that the elastic modulus of the second resin layer 12 located at the upper side of the first resin layer 11 be smaller than the elastic modulus of the first resin layer 11, and the elastic modulus of the third resin layer 13 located at the upper side of the second resin layer 12 be smaller than the elastic modulus of the second resin layer 12.

However, the order of magnitudes of the elastic modulus of the resin layers constituting the resin core 4 is not limited to the above example. The elastic modulus of the resin layers may depend on the temperature. For this reason, the resin layer where the temperature dependency of the elastic modulus is relatively large is preferably disposed at the central position to suppress the change in the elastic modulus due to the temperature change. In this case, a sandwich structure where the resin layer having a relatively small elastic modulus and a relatively large temperature dependency of the elastic modulus is disposed at the central position and is interposed by the resin layers having a relatively large elastic modulus and a relatively small temperature dependency of the elastic modulus is configured. Thereby, the resin layer that has a relatively large temperature dependency of the elastic modulus can be protected from the temperature change, and the temperature dependency of the elastic modulus in the entire resin core 4 can be greatly reduced.

<Third Modification>

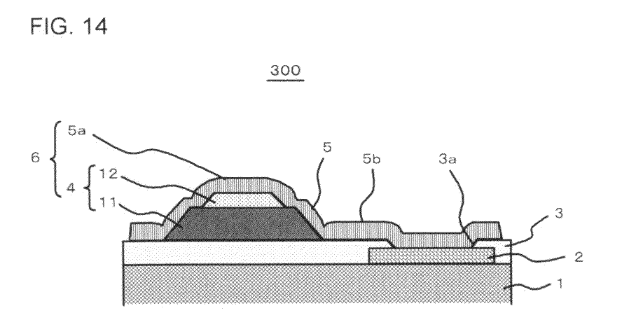

FIG. 13 is a plan view of a semiconductor device 300 according to a third modification and FIG. 14 is a cross-sectional view taken along the line A-A of FIG. 13.

In the above embodiment, the case in which the area of the bottom portion of the resin layer 12 of the upper side is approximately equal to the area of the top portion of the resin layer 11 of the lower side is exemplified. However, in the third modification, as shown in FIGS. 13 and 14, at least a second resin layer 12 of the upper side is formed to spread toward the bottom, and the area of the bottom portion of the second resin layer 12 of the upper side is smaller than the area of the top portion of a first resin layer 11 of the lower side.

As described above, the deformation amounts of the resin layers 11 and 12 increase as the areas of the top portions thereof decrease. For this reason, the desired deformation amount of the resin layer 12 can be obtained by using the configuration of the third modification.

By this configuration, since the occupied area of the second resin layer. 12 when the second resin layer 12 is pressed, deformed, and laterally swelled can be decreased, the fluidity at the time of filling the mounting sealing resin can be easily secured.

As a method that decreases only the area of the top portion of the second resin layer 12 by one-time exposing and developing, a method that uses additives where a development rate in the photolithography is improved is exemplified. That is, the additive is mixed with the material of the second photosensitive resin film 22 and is not mixed with the material of the first photosensitive resin film 21 or is mixed with the concentration less than the mixing concentration with respect to the second photosensitive resin film 22.

As another method that decreases the area of the top portion of the second resin layer 12, a method that adjusts a photosensitizing agent mixed with the materials of the first and second photosensitive resin films 21 and 22 and causes the inclination of the side of the second resin layer 12 to be moderated more than the inclination of the first resin layer 11 is exemplified. The first and second resin layers 11 and 12 are formed to spread toward the bottom. This is not shown in the drawings. However, as compared with the case in which the inclinations of the first and second resin layers 11 and 12 are equal to each other, the area of the top portion of the second resin layer 12 decreases and the inclination of the side becomes moderated. As a result, the deformation amount of the second resin layer 12 increases.

In the embodiment and the modifications described above, the case in which the plural resin core bumps 6 are formed apart from each other is exemplified. However, the plural resin core bumps 6 may be integrally formed. That is, the resin cores 4 may be connected to each other at the hem portions thereof.

In this case, a manufacturing method can be realized by exposing the first and second photosensitive resin films 21 and 22 to make the arrangement of the resin cores 4 to become dense. For example, if the arrangement of the first and second photosensitive resin films 21 and 22 remaining in the step of FIG. 3C is dense, remainders of the development are generated in the hem portions of the first and second photosensitive resin films 21 and 22 at the time of developing. As a result, a structure where the plural resin cores 4 and the plural resin core bumps 6 are connected to each other at the hem portions thereof can be realized.

The deformation characteristic of each resin layer is not limited to the example shown in FIG. 8 or 9. For example, the resin layer where the elastic modulus is relatively small may reach the saturation point of the deformation amount to be earlier than the resin layer where the elastic modulus is relatively large. Even in this case, adhesion and connectivity between the resin core bump 6 and the electrode 152 can be improved, as compared with the case in which the resin layer constituting the resin core 4 is one layer.

It is apparent that the present invention is not limited tot the above embodiments, and may be modified and changed without departing from the scope and spirit of the invention.

What is claimed is:

1. A semiconductor device, comprising:
an electrode pad;
a protective insulating film having an opening configured to expose said electrode pad;
a bump that includes a bump core formed on said protective insulating film and a conductive layer formed on said bump core; and
an interconnect that connects said conductive layer and said electrode pad,
wherein said bump core has a laminate structure of a plurality of resin layers that have different elastic modulus.

2. The semiconductor device according to claim 1,
wherein said bump core includes a first resin layer and a second resin layer having an elastic modulus smaller than an elastic modulus of said first resin layer and being located above said first resin layer.

3. The semiconductor device according to claim 2,
wherein said second resin layer is formed to spread toward the bottom, and an area of a bottom portion of said second resin layer is smaller than an area of a top portion of said first resin layer.

4. The semiconductor device according to claim 2,
wherein each of said first and second resin layers is formed to spread toward the bottom, and an inclination of a side of said second resin layer is moderated more than an inclination of a side of said first resin layer.

5. The semiconductor device according to claim 1,
wherein said bump core includes a first resin layer and a second resin layer having an elastic modulus greater than an elastic modulus of said first resin layer and being located under said first resin layer.

6. The semiconductor device according to claim 5,
wherein said second resin layer is adjacent to the upper layer of said first resin layer, and
an area of a bottom portion of said second resin layer is approximately equal to or greater than an area of a top portion of said first resin layer.

7. The semiconductor device according to claim 1,
wherein a pressing force that is applied to said bump when a deformation amount of said resin layer of said plurality of resin layers having a relatively small elastic modulus is saturated is weaker than a pressing force that is applied to said bump when a deformation amount of said resin layer of said plurality of resin layers having a relatively large elastic modulus is saturated.

8. An electronic apparatus, comprising:
said semiconductor device according to claim 1; and
a mounting substrate having an electrode,
wherein said bump is connected to said electrode of said mounting substrate.

9. A method for manufacturing a semiconductor device, comprising:
forming a protective insulating film having an opening configured to expose an electrode pad, on a substrate where the electrode pad is formed;
laminating a plurality of photosensitive resin films having different elastic modulus after curing, on said protective insulating film;
exposing, developing, and curing said plurality of photosensitive resin films to form a laminate structure of a plurality of resin layers having different elastic modulus on said protective insulating film as a bump core; and
forming a conductive layer extending from an upper portion of said bump core to an upper portion of said electrode pad.
